(19) United States
(12) Patent Application Publication
(10) Pub. No.: US 2026/0060018 A1
(43) Pub. Date: Feb. 26, 2026

(54) NITRIDE THERMAL ATOMIC LAYER ETCH

(71) Applicant: Lam Research Corporation, Fremont, CA (US)

(72) Inventors: Aaron Lynn Routzahn, Fremont, CA (US); Thorsten Bernd Lill, Kalaheo, HI (US); Andreas Fischer, Castro Valley, CA (US)

(21) Appl. No.: 19/106,145

(22) PCT Filed: Aug. 24, 2023
(86) PCT No.: PCT/US2023/031035

§ 371 Date: Feb. 24, 2025

Related U.S. Application Data
(60) Provisional application No. 63/374,017, filed on Aug. 31, 2022.

(51) Int. Cl. H01L 21/311; H01L 21/324; H01L 21/67

(52) U.S. Cl. CPC H01L 21/31116; H01L 21/324; H01L 21/67069; H01L 21/67103

(57) ABSTRACT

Provided are nitride atomic layer etch including in situ generating a phosphoric acid on the surface of silicon nitride layer by reacting a phosphorus containing reactant with one or more oxidants. Phosphoric acid selectively etches silicon nitride layer over silicon oxide and/or silicon.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

Semiconductor fabrication processes often involve selectively etching one or more materials in a semiconductor substrate. As the device size shrinks, and technology advances, it is challenging to selectively etch controlled amounts of materials from the substrate without compromising structural stability of device.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Provided are an atomic layer etch of a silicon nitride layer. The methods may involve reacting between phosphorus containing reactant, oxidants, and/or water vapor to in situ generate a phosphoric acid on the surface of silicon nitride layer to act as a dry etch chemistry. The phosphoric acid may etch selectively silicon nitride layer over other neighboring materials such as silicon or silicon oxide. The substrate temperature may be adjusted to above 100° C. to increase the etch rate of the silicon nitride layer.

One aspect of the disclosure relates to a method of treating a silicon nitride layer. The method may include (a) generating a phosphoric acid on a surface of the silicon nitride layer, and (b) treating the portion of the surface of the silicon nitride layer using the phosphoric acid.

In some embodiments, the method may further include (c), prior to (a), providing water vapor to form one or more monolayers of water molecules on the surface of the silicon nitride layer.

In some embodiments, the temperature at the surface of the silicon nitride layer may range between about 0° C. and about 100° C., and the pressure at the surface of the silicon nitride layer ranges between about 1 Torr and about 100 Torr.

In some embodiments, the temperature may be about 20° C., and the pressure may be about 10 Torr.

In some embodiments, generating the phosphoric acid may comprise providing a first reactant, providing a second reactant, and reacting the first reactant and the second reactant to form the phosphoric acid. The first reactant may include phosphorus. The first reactant may be selected from the group consisting of phosphine, diphosphorus trioxide (P₂O₃), phosphorus trichloride, phosphorus oxychloride, methoxy phosphine, alkyl phosphine halide, trimethyl phosphine, triethyl phosphine, tripropyl phosphine, and/or mixtures thereof. The second reactant may be selected from the group consisting of oxygen, ozone, carbon monoxide (CO), carbon dioxide (CO₂), nitrous oxide (N₂O), nitric oxide (N₂O), nitrogen dioxide (NO₂), and/or mixtures thereof.

In some embodiments, the method may further include providing water vapor, and prior to or during providing the water vapor, adjusting the temperature to no less than about 100° C.

In some embodiments, treating the surface of the silicon nitride layer may include etching a portion of the surface of the silicon nitride layer, and generating an etch byproduct.

In some embodiments, the method may further include removing an etch byproduct from the surface of the silicon nitride layer by: (i) heating to no less than about 360° C., (ii) heating to between about 100° C. and about 120° C. by reacting with hydrogen fluoride, or (iii) reacting with hydrogen fluoride. The etch byproduct may include phosphorus or silicon.

In some embodiments, generating the phosphoric acid may comprise co-flowing a first reactant including phosphorus, and a second reactant. The first reactant may be selected from the group consisting of phosphine, diphosphorus trioxide (P₂O₃), phosphorus trichloride, phosphorus oxychloride, methoxy phosphine, alkyl phosphine halide, trimethyl phosphine, triethyl phosphine, tripropyl phosphine, and/or mixtures thereof. The second reactant may be selected from the group consisting of oxygen, ozone, carbon monoxide (CO), carbon dioxide (CO₂), nitrous oxide (N₂O), nitric oxide (N₂O), nitrogen dioxide (NO₂), and/or mixtures thereof.

Another aspect of the disclosure relates to a method of etching a silicon nitride layer in a reaction chamber. The method may include providing a semiconductor substrate comprising the silicon nitride layer in the reaction chamber. The method may further include providing a first water vapor to form one or more monolayers of water molecules on the surface of the silicon nitride layer, and providing phosphine to the surface of the silicon nitride layer. The method may also include providing an oxidant to the phosphine to in situ generate a phosphoric acid on the silicon nitride layer.

In some embodiments, the temperature at the surface of the silicon nitride layer may range between about 0° C. and about 100° C., and the pressure at the surface of the silicon nitride layer may range between about 1 Torr and about 100 Torr.

In some embodiments, the temperature may be about 20° C., and the pressure may be about 10 Torr.

In some embodiments, the oxidant may be selected from the group consisting of oxygen, ozone, carbon monoxide (CO), carbon dioxide (CO), nitrous oxide (N₂O), nitric oxide (N₂O), nitrogen dioxide (NO₂), and/or mixtures thereof.

In some embodiments, the method may further include providing a second water vapor in the reaction chamber, and, prior to or during providing the water vapor, adjusting the temperature to no less than about 100° C.

In some embodiments, the method may further include generating an etch byproduct comprising silicon or phosphorus, and removing the etch byproduct from the surface of the silicon nitride layer by: (i) heating to no less than about 360° C., (ii) heating to between about 100° C. and about 120° C. by reacting with hydrogen fluoride, or (iii) reacting with hydrogen fluoride. The etch byproduct includes orthosilicic acid or phosphorus pentoxide.

Another aspect of the disclosure relates to an apparatus to process a substrate. The apparatus may include a process chamber for processing the substrate, a pedestal including one or more heating elements to heat the substrate, a gas distribution unit for delivering one or more gaseous reactants to the substrate, and a controller. The controller is configured to control the gas distribution unit to control flow rates and durations of the one or more gaseous reactants and/or vapors, and control the operation of the heating element to control the temperature of the substrate.

In some embodiments, the one or more heating elements may be positioned on the backside of the substrate.

In some embodiments, the one or more heating elements may include one or more light emitting elements (LED) units.

In some embodiments, the one or more heating elements may be configured to increase the substrate temperature up to about at 20° C./second.

In some embodiments, the pedestal may be spaced from the substrate by a predetermined distance.

In some embodiments, the pedestal may be in direct contact with the substrate.

In some embodiments, the one or more gaseous reactants may comprises: water vapor, a first reactant selected from the group consisting of: phosphine, diphosphorus trioxide (P₂O₃), phosphorus trichloride, phosphorus oxychloride, methoxy phosphine, alkyl phosphine halide, trimethyl phosphine, triethyl phosphine, tripropyl phosphine, and/or mixtures thereof; a second reactant selected from the group consisting of; oxygen, ozone, carbon monoxide (CO), carbon dioxide (CO₂), nitrous oxide (N₂O), nitric oxide (NO), nitrogen dioxide (NO₂), and/or mixtures thereof; or hydrogen fluoride.

In some embodiments, the substrate may include silicon nitride layer.

These and other aspects are discussed further below with reference to the drawings.

### BRIEF DESCRIPTION OF DRAWINGS

FIG. 1 is a process flow diagram showing a thermal atomic layer etch according to some embodiments.

FIG. 2A is a schematic of a reaction chamber for the thermal atomic layer etch according to some embodiments.

FIG. 2B is a schematic design showing arrangement of light sources according to some embodiments.

FIG. 2C is another schematic design showing arrangements of light sources according to some embodiments.

FIG. 2D is a schematic diagram showing a cross-sectional depiction of a pedestal according to some embodiments.

FIG. 2E is another schematic diagram showing a cross-sectional depiction of a pedestal according to some embodiments.

FIG. 2F is another schematic diagram showing a cross-sectional depiction of a substrate support according to some embodiments.

FIG. 3A is a schematic diagram showing a cross-sectional depiction of a feature prior to the atomic layer etch according to some embodiments.

FIG. 3B is a schematic diagram showing a cross-sectional depiction of a feature after the atomic layer etch according to some embodiments.

FIG. 4 is a process flow diagram showing a thermal atomic layer etch for the feature shown in FIGS. 3A-3B.

### DETAILED DESCRIPTION

In the following description, numerous specific details are set forth to provide a thorough understanding of the presented embodiments. The disclosed embodiments may be practiced without some or all these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

In the present disclosure, the terms “semiconductor wafer,” “wafer,” “substrate,” “semiconductor substrate,” “silicon substrate,” “features on a substrate,” and “features formed on a substrate” are used interchangeably. One of ordinary skill in the art would understand that the term “features on a substrate” can refer to one or more partially fabricated integrated circuits formed on a silicon wafer during any of many stages of integrated circuit fabrication. A wafer or substrate used in the semiconductor device industry typically has a diameter of 200 mm, or 300 mm, or 450 mm. The following detailed description assumes the present disclosure is implemented on a wafer. However, the present disclosure is not so limited. The work piece may be of various shapes, sizes, and materials. In addition to semiconductor wafers, other work pieces that may take advantage of the present disclosure include various articles such as printed circuit boards and the like.

In the present disclosure, the terms “depositing,” and “forming” are used interchangeably. Also, the terms “layer” and “film” are used interchangeably. One of ordinary skill in the art would understand that “forming” a layer in any of many stages of integrated circuit fabrication can refer to “depositing” a thin layer by one of various thin film forming methods such as physical vapor deposition (PVD), chemical vapor deposition (CVD), low pressure chemical vapor deposition (LPCVD), plasma enhanced chemical vapor deposition (PECVD), hot-wire chemical vapor deposition (hot-wire CVD), atomic layer deposition (ALD), or plasma enhanced atomic layer deposition (PEALD) due to the decreased feature sizes in a semiconductor device.

### INTRODUCTION AND CONTEXT

Provided are methods of treating a feature including a silicon nitride layer. The methods involve selectively etching the silicon nitride layer in one or more features on a substrate in a nanometer scale. The methods involve generating in situ a phosphoric acid on the surface of silicon nitride layer, followed by selectively removing at least a portion of the silicon nitride layer. The silicon nitride layer may be formed in a various deposition process such as CVD, PECVD, ALD, or PEALD.

The semiconductor devices may include 3D-NAND, 2D-NAND, DRAM (random-access memory), or logic devices. The semiconductor devices may include one or more partially fabricated integrated circuits, and may include a stack of layers of oxide, nitride, or carbide associated with one or more metal elements, or one or more metal layers, patterned or not-patterned. A patterned substate may have “features” such as pillars, poles, trenches, via or contact holes, which may be characterized by one or more of narrow and/or re-entrant openings, constrictions within the feature, and high aspect ratio (HAR). As the device density on a substrate increases and an individual feature size is getting smaller, a precise control of etch process may be critical.

For example, a high density semiconductor device fabrication requires an etch process that can reliably remove very small amounts of material from the features to meet design rules. The etch process may be designed to provide selectivity over other materials that should not be etched. In addition, the etch process may be designed to remove material with no directionality. This may be particularly critical for a small size, high aspect ratio features where a directional etch may be desirable. Minimizing or preventing collapse of features during etch may be also important for a high density semiconductor device with a small sized, high aspect ratio (HAR) features.

Etch process may include wet etch and dry etch. Wet etch is a liquid based process, and a portion of the features may be removed using a liquid etch chemistry at a suitable temperature. For example, wet etch may be performed at temperature ranging from an atmospheric temperature to 200-300° C., depending on the materials to be removed. Wet etch may be isotropic. Dry etch may use a gaseous etch chemistry such as oxygen plasma. Dry etch may be more suitable for an anisotropic etching.

One aspect of the embodiments relates to a method of removing at least a portion of silicon nitride layer on a substrate using a phosphoric acid in situ generated by reactions between water vapor, phosphine, and/or one or more oxidants. Water vapor may be supplied to form one or more monolayers of water molecules adsorbed on the silicon nitride layer. Alternately, water vapor may be provided from an atmosphere in the reaction chamber. Phosphine reacts with water to in situ form phosphoric acid. The phosphoric acid may also be in situ generated by hydrating phosphorus oxide (P₂O₅) generated by reacting phosphine with one or more oxidants. One or more oxidants may be oxygen, ozone, carbon monoxide (CO), carbon dioxide (CO₂), nitrous oxide (N₂O), nitric oxide (NO), nitrogen dioxide (NO₂), and/or mixtures thereof. Subsequently, water vapor may be provided and the substrate temperature may be increased to above 100° C. to increase the reactivity of phosphoric acid and the etch rate of silicon nitride layer.

Another aspect of the embodiments relates to a method of selectively etching a portion of silicon nitride layer on a substrate using a phosphoric acid in situ generated by reacting phosphine with one or more oxidants. One or more oxidants may be oxygen, ozone, carbon monoxide (CO), carbon dioxide (CO₂), nitrous oxide (N₂O), nitric oxide (NO), nitrogen dioxide (NO₂), and/or mixtures thereof. The phosphoric acid may be uniformly formed on the surface of the silicon nitride layer. Providing water vapor to the phosphoric acid may increase the reactivity of the phosphoric acid and etch rate of the silicon nitride layer. The substrate temperature may be adjusted to above 100° C. to further increase the etch rate of the silicon nitride layer. The phosphoric acid may selectively etch the silicon nitride layer over neighboring materials such as silicon or silicon oxide.

Still another aspect of the embodiments relates to a method of removing one or more etch byproducts generated during silicon nitride layer etch. Etch byproducts may include silicon and/or phosphorus, and may remain on surfaces of silicon nitride layer. Silicon containing etch byproducts may be removed by reacting with hydrogen fluoride (HF) at between about 100° C. and about 120° C. to generate a volatile etch byproduct, e.g., silicon tetrafluoride. Phosphorus containing etch byproducts may be removed by reacting with hydrogen fluoride at above 100° C., or by thermal sublimation above about 360° C., or above about 375° C., or above about 400° C.

Still yet another aspect of the embodiments relates to a method of etching a silicon nitride layer followed by depositing one or more silicon-containing layers on a substrate without breaking a vacuum in a reaction chamber or exposing the substrate to an ambient atmosphere. The one or more silicon-containing layers may be deposited by CVD, PECVD, ALD, or PEALD.

Provided also herein are apparatuses for semiconductor processing, for example, to etch a semiconductor substrate using thermal energy, rather than or in addition to plasma energy. In various embodiments, apparatuses described herein are designed or configured to rapidly heat and cool a substrate, and precisely and uniformly control a substrate's temperature. In some embodiments, the substrate is rapidly heated and its temperature is precisely controlled using, in part, visible light emitted from light emitting diodes (LEDs) positioned in a pedestal under the substrate. The visible light may have wavelengths that include and range between 400 nm and 800 nm. The pedestal may include various features for enabling substrate temperature control, such as a transparent window that may have lensing for advantageously directing or focusing the emitted light, reflective material also for advantageously directing or focusing the emitted light, and temperature control elements that assist with temperature control of the LEDs, the pedestal, and the chamber.

The apparatuses may also thermally isolate, or thermally “float,” the substrate within the processing chamber so that only the smallest thermal mass is heated, the ideal smallest thermal mass being just the substrate itself, which enables faster heating and cooling. The substrate may be rapidly cooled using a cooling gas and radiative heat transfer to a heat sink, such as a top plate (or other gas distribution element) above the substrate, or both. In some instances, the apparatuses may also include temperature control elements within the processing chamber walls, pedestal, and top plate (or other gas distribution element), to enable further temperature control of the substrate and processing conditions within the chamber, such the prevention of unwanted condensation of processing gases and vapors.

The apparatuses may also be configured to implement various control loops to precisely control the substrate and the chamber temperatures (e.g., with a controller configured to execute instructions that cause the apparatus to perform these loops). This may include the use of various sensors that determine substrate and chamber temperatures as part of open loops and feedback control loops. These sensors may include temperature sensors in the substrate supports which contact the substrate and measure its temperature, and non-contact sensors such as photodetectors to measure light output of the LEDs and a pyrometer configured to measure the temperature of different types of substrates. As described in more detail below, some pyrometers determine an item's temperature by emitting infrared or other optical signals at the item and measuring the signals reflected or emitted by the item. However, the temperature of many silicon substrates cannot be measured by some pyrometers because the silicon can be optically transparent at various temperatures and with various treatments, e.g., doped or low doped silicon. For example, a low doped silicon substrate at a temperature less than 200° C. is transparent to infrared signals. The pyrometers provided herein are able to measure multiple types of silicon substrates at various temperatures.

### Thermal Atomic Layer Etch

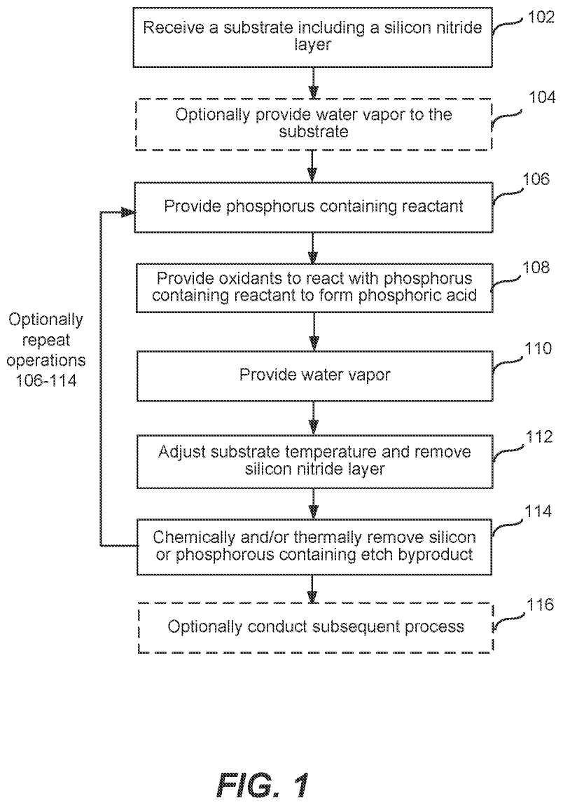

FIG. 1 is a process flow diagram describing a method to conduct a thermal atomic layer etch for a substrate according to some embodiments. The substrate may include one or more features. The one or more features may include a stack of materials having different chemical compositions. The stack may include alternating layers of materials with different compositions. The one or more features may include a material to be etched and a material that is not to be etched. In some embodiments, the material to be removed may be silicon nitride. In some embodiments, the material that is not to be removed may be silicon oxide or silicon. Examples of applications for a thermal atomic layer etch according to some embodiments include features in 2D-NAND, 3D-NAND, DRAM, and logic devices. While the method in FIG. 1 is described for generating phosphoric acid from a phosphine, the method in FIG. 1 is not limiting. It is to be understood that any phosphorus containing reactant described herein may be replaced with phosphine and used in generating phosphoric acid.

The method begins by providing a substrate at operation 102. The substrate may be provided in a reaction chamber using a transfer tool. Once provided in the reaction chamber, the substrate may be supported on a pedestal. After providing a substrate, an optional cleaning step may be performed. The optional cleaning may remove any oxide layer or undesirable materials formed on the surface of the features on the substrate. In some embodiments, a chlorine (Cl)-based plasma, a hydrogen fluoride (HF) vapor clean, an ammonium fluoride (NH₄F) clean, or a treatment using other reducing agents may be used to reduce oxide of Si undesirably formed on the features or substrate. One or more features including one or more layers described herein may be formed on the substrate prior to the operation 102 by any suitable process including but not limited to CVD, PECVD, ALD, or PEALD. In some embodiments, the one or more layers may be adsorbed on the silicon nitride layer.

In optional operation 104, water vapor is supplied to the chamber interior according to a process recipe. In some embodiments, a controller and a switching system may control the flow rate and duration of water vapor into the chamber interior. In some embodiments, the flow rate and duration of water vapor may be configured such that water vapor does not condense on the surface of the silicon nitride layer. For example, about one to about ten monolayers of water molecules may be adsorbed on the surface of the features. One or more monolayers of water molecules may be configured to uniformly cover the surface of features on the substrate or the surface of the silicon nitride layer.

The temperature and pressure may affect the amount of the water molecules adsorbed. For example, the amount of water adsorption on a surface may be inversely proportional to the temperature and proportional to the pressure. During the optional operation 104, the substrate temperature may be between about 0° C. and 100° C., or between about 10° C. and 50° C., or between about 10° C. and 30° C., or about 20° C. In some embodiments, the chamber temperature may be substantially the same as the substrate temperature. In some embodiments, the chamber temperature, the temperature for substrate, silicon nitride layer, and/or water vapor may be configured to be substantially identical to each other. The chamber pressure during the operation 104 may be adjusted to between about 1 Torr and 100 Torr, or between about 5 Torr and 50 Torr, or about 10 Torr.

In operation 106, a phosphorus containing reactant may be provided. In one example, the phosphorus containing reactant may be a gaseous reactant. One example may include gaseous phosphine. On the other hand, it is to be understood that the process flow in FIG. 1 is not limited to phosphine. That being said, other phosphorus containing reactant may also be replaced with phosphine to in situ generate phosphoric acid on the surface of the silicon nitride according to some embodiments. For example, phosphine, diphosphorus trioxide (P₂O₃), phosphorus trichloride, phosphorus oxychloride, methoxy phosphine, alkyl phosphine halide, trimethyl phosphine, triethyl phosphine, tripropyl phosphine, and/or mixtures thereof may be used as the phosphorus containing reactant.

Where water vapor is provided to the surface of the silicon nitride at operation 104, phosphine may react with water to in situ form phosphoric acid (H₃PO₄). Reaction of phosphine with water may increase the solubility of phosphine in water and facilitates the formation of the phosphoric acid. In the absence of water molecule adsorbed on the feature surface by providing water vapor, phosphine may still react with water molecule (humidity) within the reaction chamber to form phosphoric acid.

The amount of phosphoric acid generated from the reaction with water may depend on, for example, the relative amount of water in the chamber atmosphere with respect to the amount of phosphine. In some embodiments, a portion of phosphine may be consumed to react with water in the chamber atmosphere to generate phosphoric acid while a portion of phosphine still may remain unreacted on the surface of the features. For example, depending on the amount of phosphine, excess phosphine may not react with water and may remain unreacted on the surface of the silicon nitride layer. Accordingly, a mixture of phosphine and phosphoric acid may present on the surface of the silicon nitride layer. In some embodiment, the substrate temperature and chamber pressure during the operation 106 may be substantially the same as the operation 104. For example, the substrate temperature at operation 106 may be between about 0° C. and 100° C., or between about 0° C. and 50° C., or between about 10° C. and 30° C., or about 20° C. The chamber pressure at operation 106 may be adjusted to between about 1 Torr and 100 Torr, or between about 5 Torr and 50 Torr, or about 10 Torr.

In operation 108, one or more oxidants may be provided into the reaction chamber. The oxidants may react with phosphine on the surface of the silicon nitride layer where unreacted phosphine remains. Phosphine may be oxidized by one or more oxidants to form phosphorus oxide (P₂O₅). P₂O₅ may be hydrated by water that may present on or near the silicon nitride surface to in situ generate phosphoric acid. Example oxidants include oxygen, ozone, carbon monoxide (CO), carbon dioxide (CO₂), nitrous oxide (N₂O), nitric oxide (N₂O), nitrogen dioxide (NO₂), and/or mixtures thereof.

It is to be understood that, while the operation 106 and operation 108 can be performed sequentially as described, the operations 106 and 108 may be conducted concurrently or substantially concurrently. In an example, phosphine and ozone (or oxygen or other oxidants) may co-flow through the fluid inlets into the chamber interior. Phosphine may react with water (from the reaction chamber atmosphere or water vapor provided to the substrate surface in optional operation 104) to in situ generate phosphoric acid. Concurrently or substantially concurrently, unreacted phosphine may be oxidized by oxidants and hydrated to form phosphoric acid. The substrate temperature and chamber pressure during the operation 108 may be maintained to be substantially the same as the substrate temperature and chamber pressure at operations 104 and/or 106.

In operation 110, water vapor may be supplied into the reaction chamber. In some embodiments, the flow rate and duration of water vapor may be configured to avoid condensation of water vapor on the features. Providing additional water vapor at operation 110 may increase the concentration and/or reactivity of phosphoric acid. Accordingly, an etch rate for silicon nitride layer at operation 110 may be greater than etch rates at operations 106 and/or 108. The substrate temperature and chamber pressure during the operation 110 may be maintained to be substantially the same as the substrate temperature and chamber pressure at operations 104-108.

At operation 112, the substrate temperature may be increased to above to above 100° C., or between about 100° C. and about 180° C., or between about 120° C. and about 180° C. In some embodiments, the substrate temperature may be configured to increase prior to onset of operation 112. Increasing the substrate temperature at operation 112 may increase the etch rate of the silicon nitride. More uniform nitride etch may be obtained for a faster ramp rate at operation 112. For example, the substrate temperature may be configured to increase at a ramp rate of about 20° C./second. Accordingly, operation 112 may involve substantially etching the silicon nitride layer. The etch rate for a silicon nitride layer at operation 112 may be significantly greater than the etch rates at other operations. For example, most or substantially all of the etch process may be performed at operation 112. During the nitride etch at operation 112, one or more etch byproducts may be generated. The one or more etch byproducts may include silicon or phosphorus, which may be non-volatile. The pressure at operation 112 may be configured to range between about 1 Torr and about 100 Torr.

The nitride etch according to some embodiments may be a dry etch process performed by providing gaseous and/or vapor reactants to the surface of the silicon nitride layers in the features. A silicon nitride layer is etched by the exposing the silicon nitride layer to in situ generated phosphoric acid. Phosphoric acid may be in situ generated via combination of different reaction routes. For example, water vapor at operation 104 may increase the solubility of phosphine (or other phosphorus containing reactant) that is provided at operation 106, and in situ generate phosphoric acid. Phosphoric acid may be generated by hydrating phosphorus oxide (P₂O₅), which is formed by reacting phosphine (or other phosphorus containing reactant) with one or more oxidants. Regardless of routes, the phosphoric acid generated may include gaseous etch chemistry. Therefore, the phosphoric acid according to some embodiments may uniformly cover and adsorb on the surface of the features without providing excess etch chemistry to a local area on the substrate. This is especially advantageous for a semiconductor device including high density, smaller sized features, where having non-uniform, excess etch chemistry may lead to a non-uniform etch rate, and jeopardize the structural stability of the features and increase the probability of device failure.

At operation 114, one or more etch byproducts may be removed by thermal process or combination of chemical and thermal processes. In one example, orthosilicic acid (Si(OH)₄) may present as an etch byproduct on the surface of the silicon nitride. Si(OH)₄ may be non-volatile. Si(OH)₄ on the substrate may be heated above about 100° C., or above 120° C., or between about 100° C. and about 120° C., or above 130° C., or above 140° C., or above 150° C. while reacting with hydrogen fluoride (HF) vapor. This combination of chemical and thermal processes may generate a volatile silicon tetrafluoride (SiF₄) without substantially reacting with other neighboring material such as silicon or silicon oxide (SiO₂) as HF does not react with silicon oxide in the absence of water at elevated temperature. The volatile SiF₄ may be removed out of the reaction chamber.

In another example, excess phosphoric acid may remain on the surface of silicon nitride layer without being fully consumed in operations 106-112. A substrate may be heated to above 100° C. to remove any water molecule from phosphoric acid to leave P₂O₅ on the substrate surface. HF vapor may be supplied to P₂O₅ to form a volatile phosphorus containing byproduct, e.g., phosphorus pentafluoride (PF₅). Alternately, P₂O₅ may be removed by sublimation without being assisted by HF or other reducing agents. P₂O₅ may have a boiling point of about 350-360° C. Heating the substrate with remaining P₂O₅ further above about 360° C., or above about 375° C., or above about 400° C. may sublime P₂O₅ from the features, leaving the features P₂O₅ free. The duration of sublimation may range from about 5 seconds to about 600 seconds.

After operation 114 is complete, it may be determined whether the features or substrate including silicon nitride layer is further etched according to device design. In case where silicon nitride layer may need to be further etched, operations 104-114 (or operations 106-114) may be repeated until the desired etching is obtained. For example, the number of cycles for nitride atomic layer etch may depend on the dimension of features such as a depth of silicon nitride layer in the stack, or the like.

After operation 114, a subsequent process may be optionally undertaken. For example, one or more silicon-containing layers may be deposited after etch byproducts are removed from the silicon nitride surface as described herein. The one or more silicon-containing layer may be formed in a suitable deposition process such as CVD, PECVD, ALD, PEALD, or any other deposition technique. In another example, another substrate may be transferred to the reaction chamber for a silicon nitride layer etch. It is noted that the reaction chamber may be configured to deposit one or more layers of oxide, nitride, carbide, oxynitride, oxycarbide, or oxycarbide associate with one or more metal elements, or one or more metal layers, and selectively etch at least a portion of the layers deposited prior to the selective etch without breaking vacuum or exposing a substrate to an ambient atmosphere.

### Apparatus

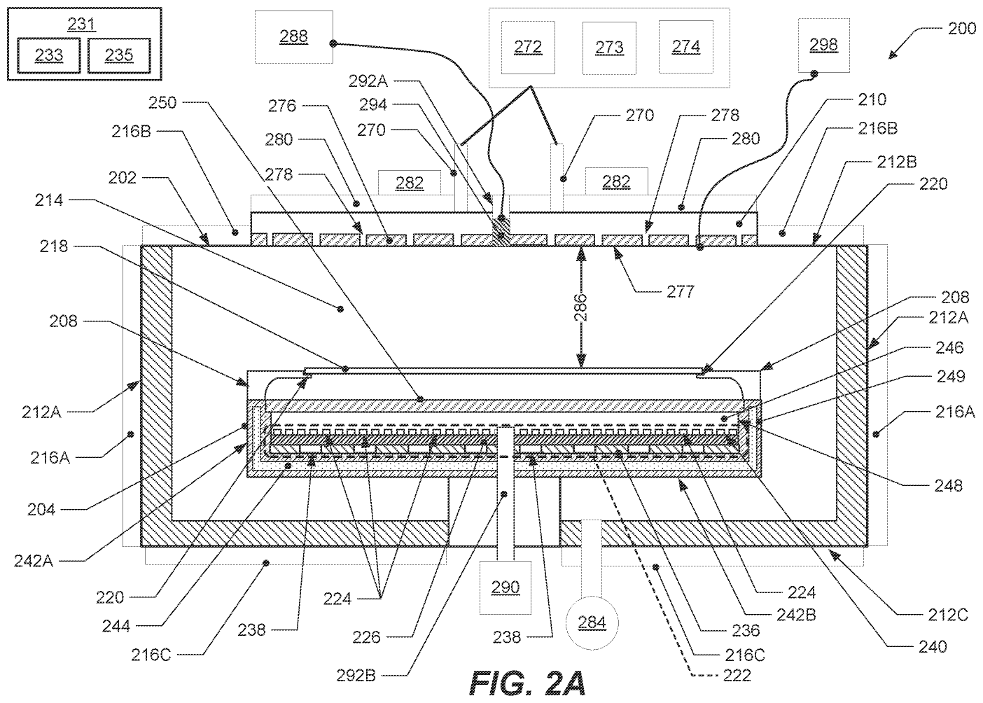

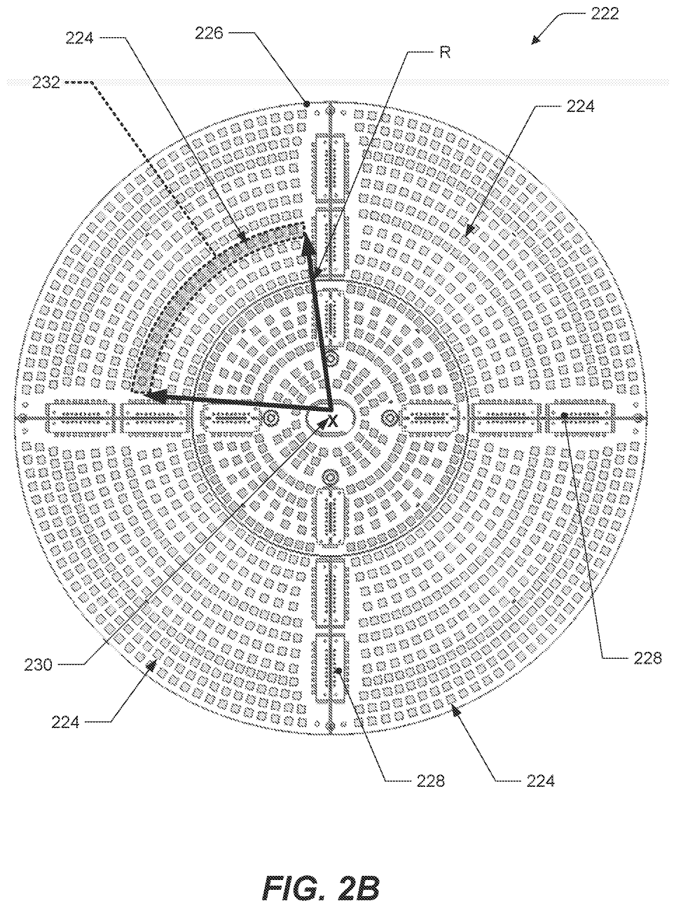

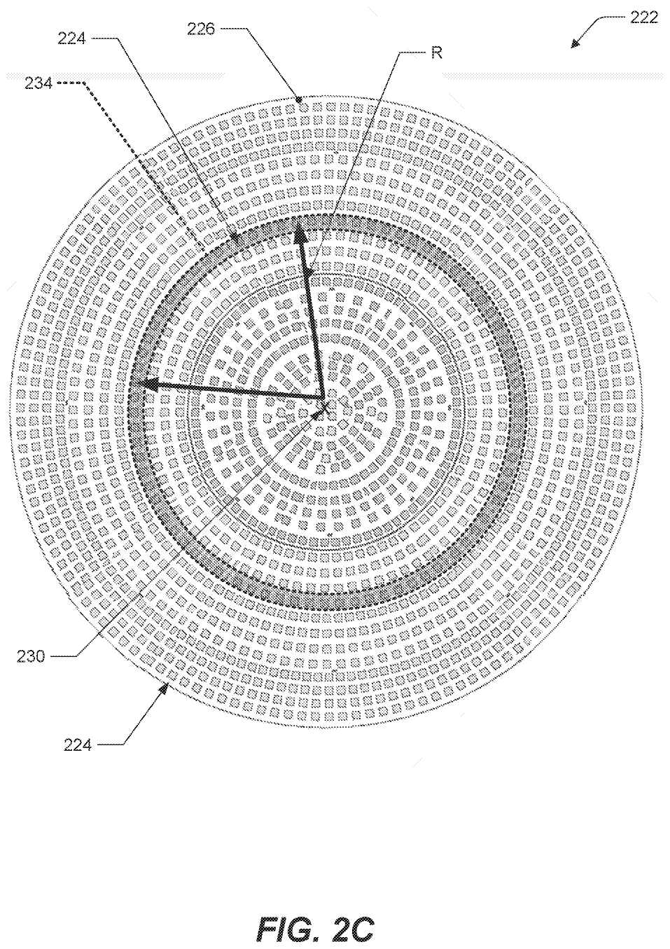

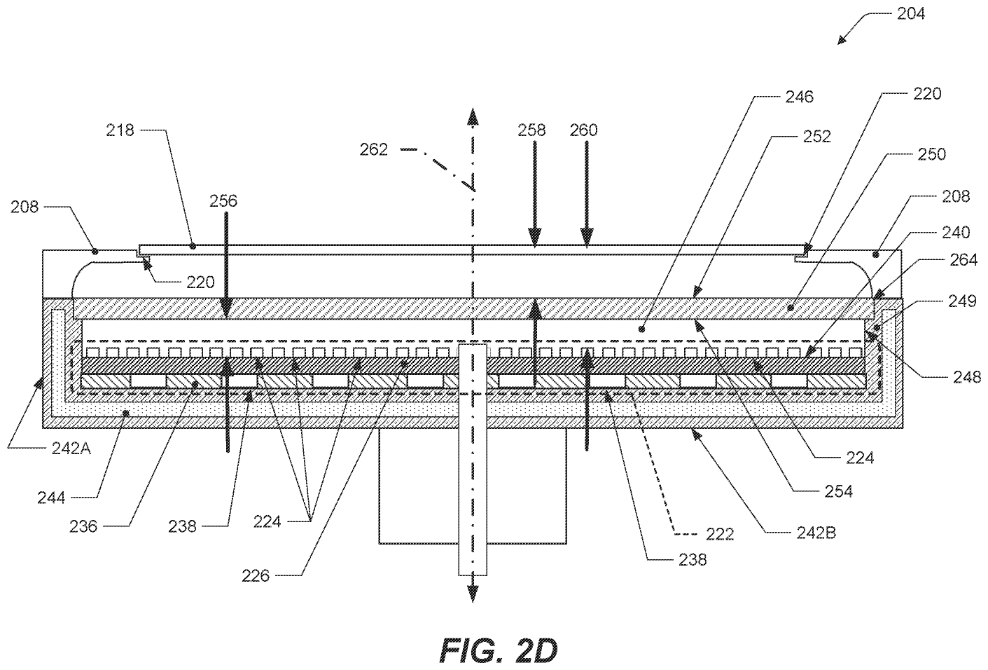

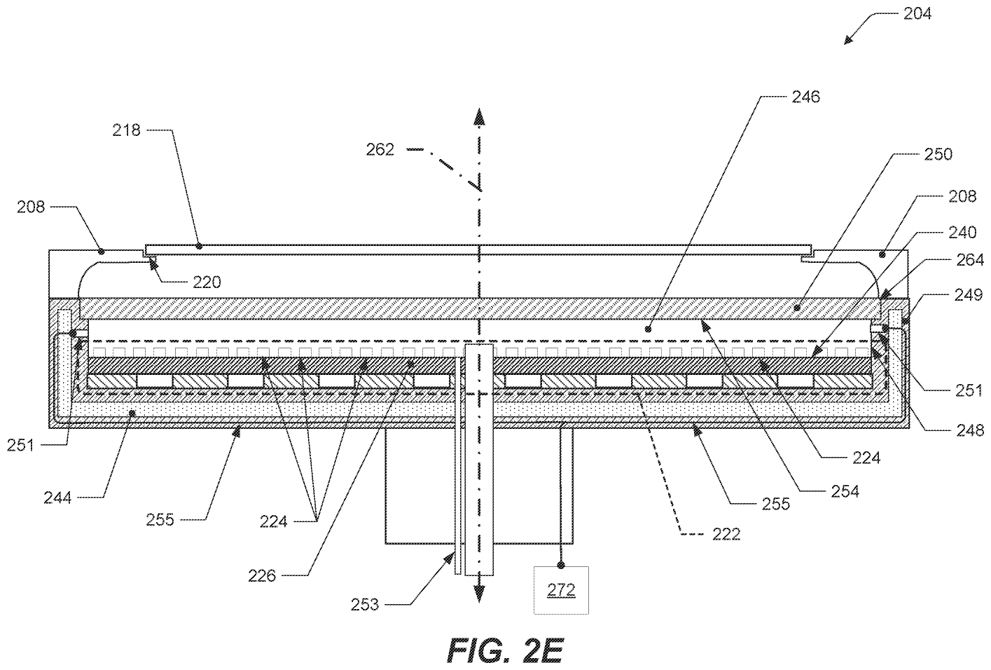

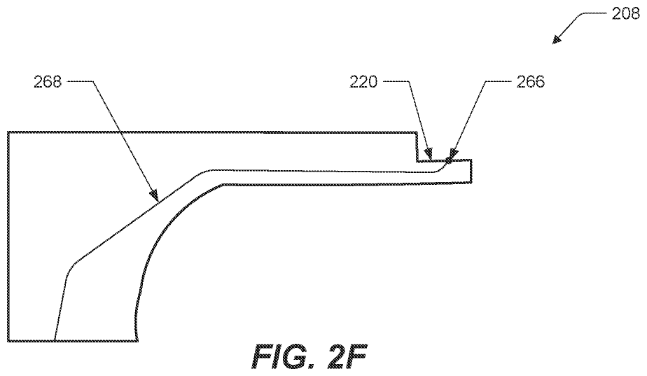

FIG. 2A depicts a cross-sectional side view of an example apparatus in accordance with some embodiments. As detailed below, this apparatus 200 is capable of rapidly and precisely controlling the temperature of a substrate, including performing thermal etching operations, an example of which is a Prevos™ selective Etch Tool, produced by Lam Research Corporation of Fremont, California.

The apparatus 200 includes a processing chamber 202, a pedestal 204 having a plurality of substrate supports 208 configured to support a substrate 218, and a gas distribution unit 210. The processing chamber 202 includes sides walls 212A, a top 212B, and a bottom 212C, that at least partially define the chamber interior 214, which may be considered a plenum volume. As stated herein, it may be desirable in some embodiments to actively control the temperature of the processing chamber walls 212A, top 212B, and bottom 212C in order to prevent unwanted condensation on their surfaces. Some emerging semiconductor processing operations flow vapors, such as water and/or alcohol vapor, onto the substrate which adsorb onto the substrate, but they may also undesirably adsorb onto the chamber's interior surfaces. This can lead to unwanted deposition and etching on the chamber interior surfaces which can damage the chamber surfaces and cause particulates to flake off onto the substrate thereby causing substrate defects. In order to reduce and prevent unwanted condensation on the chamber's interior surfaces, the temperature of chamber's walls, top, and bottom may be maintained at a temperature at which condensation of chemistries used in the processing operations does not occur.

This active temperature control of the chamber's surfaces may be achieved by using heaters to heat the chamber walls 212A, the top 212B, and the bottom 212C. As illustrated in FIG. 2A, chamber heaters 216A are positioned on and configured to heat the chamber walls 212A, chamber heaters 216B are positioned on and configured to heat the top 212B, and chamber heaters 216C are positioned on and configured to heat the bottom 212C. The chamber heaters 216A-216C may be resistive heaters that are configured to generate heat when an electrical current is flowed through a resistive element. Chamber heaters 216A-216C may also be fluid conduits through which a heat transfer fluid may be flowed, such as a heating fluid which may include heated water. In some instances, the chamber heaters 216A-216C may be a combination of both heating fluid and resistive heaters. The chamber heaters 216A-216C are configured to generate heat in order to cause the interior surfaces of each of the chamber walls 212A, the top 212B, and the bottom 212C to the desired temperature, which may range between about 40° C. and about 400° C., about 40° C. and about 250° C., about 40° C. and about 150° C., including between about 80° C. and about 130° C., about 90° C., or about 120° C., for instance. It has been discovered that under some conditions, water and alcohol vapors do not condense on surfaces kept at about 90° C. or higher. While not shown in FIG. 2A, chamber heaters 216A-216C may include one or more temperature sensors operably coupled to the chamber heaters 216A-216C to monitor the chamber temperature.

The chamber walls 212A, top 212B, and bottom 212C, may also be comprised of various materials that can withstand the chemistries used in the processing techniques. These chamber materials may include, for example, an aluminum, anodized aluminum, aluminum with a polymer, such as a plastic, a metal or metal alloy with a yttria coating, a metal or metal alloy with a zirconia coating, and a metal or metal alloy with aluminum oxide coating; in some instances the materials of the coatings may be blended or layers of differing material combinations, such as alternating layers of aluminum oxide and yttria, or aluminum oxide and zirconia. These materials are configured to withstand the chemistries used in the processing techniques, such as anhydrous HF, water vapor, methanol, isopropyl alcohol, chlorine, fluorine gases, nitrogen gas, hydrogen gas, helium gas, and/or mixtures thereof.

The apparatus 200 may also be configured to perform processing operations at or near a vacuum, such as at a pressure of about 0.1 Torr to about 100 Torr, about 20 Torr to about 200 Torr, about 0.1 Torr to about 10 Torr, or about 10 Torr. The apparatus 200 may include a vacuum pump 284 configured to pump the chamber interior 214 to low pressures, such as a vacuum having a pressure of about 0.1 Torr to about 100 Torr, including about 0.1 Torr to about 10 Torr, about 20 Torr to about 200 Torr, about 0.1 Torr to about 10 Torr, or about 10 Torr.

Various features of the pedestal 204 will now be discussed. The pedestal 204 includes a heater 222 (encompassed by the dashed rectangle in FIG. 2A) that has a plurality of LEDs 224 that are configured to emit visible light having wavelengths including and between 400 nm to 800 nm, including 450 nm. The heater LEDs emit this visible light onto the backside of the substrate which heats the substrate. Visible light having wavelengths from about 400 nm to 800 nm is able to quickly and efficiently heat silicon substrates from ambient temperature, e.g., about 20° C., to temperatures as high as about 600° C. because silicon absorbs visible light within this range. In contrast, radiant heating, including infrared radiant heating, may ineffectively heat silicon at temperatures up to about 400° C. because silicon tends to be transparent to infrared at temperatures lower than about 400° C. Additionally, radiant heaters that directly heat the topside of a substrate, as in many conventional semiconductor processes, can cause damage or other adverse effects to the topside films. Many “hot plate” heaters that rely on solid-to-solid thermal transference between the substrate and a heating platen, such as a pedestal with a heating coil, have relatively slow to heating and cooling rates, and provide non-uniform heating which may be caused by substrate warping and inconsistent contact with the heating platen. For example, it may take multiple minutes to heat some pedestals to a desired temperature, and from a first to a second higher temperature, as well as to cool the pedestal to a lower temperature.

The heater's plurality of LEDs may be arranged, electrically connected, and electrically controlled in various manners. Each LED may be configured to emit a visible blue light and/or a visible white light. In certain embodiments, white light (produced using a range of wavelengths in the visible portion of the EM spectrum) is used. In some semiconductor processing operations, white light can reduce or prevent unwanted thin film interference. For instance, some substrates have backside films that reflect different light wavelengths in various amounts, thereby creating an uneven and potentially inefficient heating. Using white light can reduce this unwanted reflection variation by averaging out the thin film interference over the broad visible spectrum provided by white light. In some instances, depending on the material on the back face of the substrate, it may be advantageous to use a visible non-white light, such as a blue light having a 450 nm wavelength, for example, in order to provide a single or narrow band of wavelength which may provide more efficient, powerful, and direct heating of some substrates that may absorb the narrow band wavelength better than white light.

Various types of LED may be employed. Examples include a chip on board (COB) LED or a surface mounted diode (SMD) LED. For SMD LEDs, the LED chip may be fused to a printed circuit board (PCB) that may have multiple electrical contacts allowing for the control of each diode on the chip. For example, a single SMD chip may have three diodes (e.g., red, blue, or green) that can be individually controllable to create different colors, for instance. SMD LED chips may range in size, such as 2.8×2.5 mm, 3.0×3.0 mm, 3.5×2.8 mm, 5.0′×5.0 mm, and 5.6×3.0 mm. For COB LEDs, each chip can have more than three diodes, such as nine, 12, tens, hundreds or more, printed on the same PCB. COB LED chips typically have one circuit and two contacts regardless of the number of diodes, thereby providing a simple design and efficient single color application. The ability and performance of LEDs to heat the substrate may be measured by the watts of heat emitted by each LED; these watts of heat may directly contribute to heating the substrate.

FIG. 2B depicts a top view of a substrate heater with a plurality LEDs. This substrate heater 222 includes a printed circuit board 226 and the plurality of LEDs 224, some of which are labeled; this depicted plurality includes approximately 1,300 LEDs. External connections 228 are connected by traces to provide power to the plurality of LEDs 224. As illustrated in FIG. 2B, the LEDs may be arranged along numerous arcs that are radially offset from the center 230 of the substrate heater 222 by different radiuses; in each arc, the LEDs may be equally spaced from each other. For example, one arc 232 is surrounded by a partially shaded dotted shape, includes 16 LEDs 224, and is a part of a circle with a radius R that extends around the center 230. The 16 LEDs 224 may be considered equally spaced from each other along this arc 232.

In some embodiments, the LEDs may also be arranged along circles around the center of the substrate heater. In some instances, some LEDs may be arranged along circles while others may be arranged along arcs. FIG. 2C depicts a top view of another example of a substrate heater with a plurality LEDs. The substrate heater 222 of FIG. 2C includes a printed circuit board 226 and the plurality of LEDs 224, some of which are labeled. Here, LEDs 224 are arranged along numerous circles that are radially offset from the center 230 of the substrate heater 222 by different radiuses; in each circle, the LEDs may be equally spaced from each other. For example, one circle 234 is surrounded by a partially shaded ring, includes 78 LEDs 224, and has a radius R that extends around the center 230. The 78 LEDs 224 may be considered equally spaced from each other along this circle 234. The arrangement of the LEDs in FIG. 2C may provide a more uniform light and heat distribution pattern across the entire backside of the substrate compared to the arrangement in FIG. 2B because the regions of the substrate heater 222 in FIG. 2B that contain the external connections may provide unheated cold spots on the substrate, especially because the substrate and heater remain stationary with respect to each other during processing; the substrate and the substrate heater do not rotate.

In some embodiments, the plurality of LEDs may include at least about 1,000 LEDs, including about 1,200, 1,500, 2,000, 3,000, 4,000, 5,000, or more than 6,000, for instance. Each LED may, in some instances, be configured to uses about 4 watts or less at 100% power, including about 3 watts at 100% power and about 1 watt at 100% power. These LEDs may be arranged and electrically connected into individually controllable zones to enable temperature adjustment and fine tuning across the substrate. In some instances, the LEDs may be grouped into at least 20, for instance, independently controllable zones, including at least about 25, 50, 75, 80, 85 90, 95, or 100 zones, for instance. These zones may allow for temperature adjustments in the radial and azimuthal (i.e., angular) directions. These zones can be arranged in a defined pattern, such as a rectangular grid, a hexagonal grid, or other suitable pattern for generating a temperature profile as desired. The zones may also have varying shapes, such as square, trapezoidal, rectangular, triangular, obround, elliptical, circular, annular (e.g., a ring), partially annular (e.g., an annular sector), an arc, a segment, and a sector that may be centered on the center of the heater and have a radius less than or equal to the overall radius of the substrate heater's PCB. For example, in FIG. 2B the LEDs have 88 zones that are organized into at least 20, such as 20 or 21, concentric rings. These zones are able to adjust the temperature at numerous locations across the substrate in order to create a more even temperature distribution as well as desired temperature profiles, such as higher temperatures around the edge of the substrate than in the center of the substrate. The independent control of these zones may also include the ability to control the power output of each zone. For example, each zone may have at least 15, 20, or 25 adjustable power outputs. In some instances, each zone may have one LED thereby enabling each LED to be individually controlled and adjusted which can lead to a more uniform heating profile on the substrate. Accordingly, in some embodiments, each LED of the plurality of LEDs in the substrate heater may be individually controllable.

In certain embodiments, the substrate heater 222 is configured to heat the substrate to multiple temperatures and maintain each such temperature for various durations. The substrate heater may be configured to heat the substrate to between about 50° C. and 600° C., including to any temperature or range between these temperatures. Additionally, in some embodiments, the substrate heater 222 is configured to heat the substrate to any temperature within these ranges in less than about 60 seconds, less than about 45 seconds, less than about 30 seconds, or less than about 15 seconds, for instance. In certain embodiments, the substrate heater 222 is configured to heat a substrate at one or more heating rates, such as between at least about 0.1° C./second and at least about 20° C./second, for example.

The substrate heater may increase the temperature of the substrate by causing the LEDs to emit the visible light at one or more power levels, including at least about 80%, at least about 90%, at least about 95%, or at least about 100% power. In some embodiments, the substrate heater is configured to emit light between about 10 W and 4000 W, including at least about 10 W, at least about 30 W, at least about 0.3 kilowatt (kW), at least about 0.5 kW, at least about 2 kW, at least about 3 kW, or at least about 4 kw. The apparatus is configured to supply between about 0.1 kw and 9 kW of power to the pedestal, the power supply is connected to the substrate heater through the pedestal but is not depicted in the Figures. During temperature ramps, the substrate heater may operate at the high powers, and may operate at the lower power levels (e.g., including between about 5 W and about 0.5 kW) to maintain the temperature of a heated substrate.

The pedestal may include reflective material on its internal surfaces that, during operation, reflects and directs the light emitted by the LEDs onto the backside of the substrate supported by the pedestal. In some such embodiments, the substrate heater may include such reflective material positioned on a top surface 240, as shown in FIG. 2A, of the PCB 226 on which the plurality of LEDs 224 is positioned. The reflective material may be comprised of aluminum, such as polished aluminum, stainless steel, aluminum alloys, nickel alloys, and other protective layers which can prevent oxidation of the metal and/or enhance the reflectivity at specific wavelengths, such as reaching greater than 99% reflectivity for specific wavelengths, and other durable reflective coatings. Additionally or alternatively, the pedestal 204 may have a bowl 246 in which the substrate heater 222 is at least partially positioned. The bowl 246 may have exposed internal surfaces 248 of the pedestal sidewalls 249 upon which the reflective material may be positioned. This reflective material increases the heating efficiency of the substrate heater and reduces the unwanted heating of the PCB 226 and pedestal 204 by advantageously directing light back onto the substrate that would have otherwise been absorbed by the PCB 226 and the pedestal 204.

In some embodiments, the substrate heater may also include a pedestal cooler that is thermally connected to the LEDs such that heat generated by the plurality of LEDs can be transferred from the LEDs to the pedestal cooler. This thermal connection is such that heat can be conducted from the plurality of LEDs to the pedestal cooler along one or more heat flow pathways between these components. In some instances, the pedestal cooler is in direct contact with one or more elements of the substrate heater, while in other instances other conductive elements, such as thermally conductive plates (e.g., that comprise a metal) are interposed between the substrate heater and the pedestal cooler. Referring back to FIG. 2A, the substrate heater includes a pedestal cooler 236 in direct contact with the bottom of the PCB 226. Heat is configured to flow from the LEDs, to the PCB 226, and to the pedestal cooler 236. The pedestal cooler 236 also includes a plurality of fluid conduits 238 through which a heat transfer fluid, such as water, is configured to flow in order to receive the heat and thus cool the LEDs in the substrate heater 222. The fluid conduits 238 may be connected to a reservoir and pump, not pictured, located outside the chamber. In some instances, the pedestal cooler may be configured to flow water that is cooled, such as between about 5° C. and 20° C.

As provided herein, it may be advantageous to actively heat the exterior surfaces of the processing chamber 202. In some instances, it may similarly be advantageous to heat the exterior surfaces of the pedestal 204 in order to prevent unwanted condensation and deposition on its external surfaces. As illustrated in FIG. 2A, the pedestal 204 may further include a pedestal heater 244 inside of the pedestal 204 that is configured to heat the exterior surfaces of the pedestal 204, including its sides 242A and bottom 242B. The pedestal heater 244 may include one or more heating elements, such as one or more resistive heating elements and fluid conduits in which a heating fluid is configured to flow. In some instances, the pedestal cooler and the pedestal heater may both have fluid conduits that are fluidically connected to each other such that the same heat transfer fluid may flow in both the pedestal cooler and the pedestal heater. In these embodiments, the fluid may be heated to between 50° C. and 130° C. including about 90° C. and 120° C.

The pedestal may also include a window to protect the substrate heater, including the plurality of LEDs, from damage caused by exposure to the processing chemistries and pressures used during processing operations. As illustrated in FIG. 2A, the window 250 may be positioned above the substrate heater 222 and may be sealed to the sidewall 249 of the pedestal 204 in order to create a plenum volume within the pedestal that is fluidically isolated from the chamber interior. This plenum volume may also be considered the inside of the bowl 246. The window may be comprised of one or more materials that are optically transparent to the visible light emitted by LEDs, including light having wavelengths in the range of 400 nm to 800 nm. In some embodiments, this material may be quartz, sapphire, quartz with a sapphire coating, or calcium fluoride (CaF). The window may also not have any holes or openings within it. In some embodiments, the heater may have a thickness of about 15 to 30 mm, including about 20 mm and about 25 mm.

FIG. 2D depicts the pedestal of FIG. 2A with additional features in accordance with various embodiments. As identified in FIG. 2D, the window 250 includes a top surface 252 that faces the substrate 218 supported by the pedestal 204, and a bottom surface 254 that faces the substrate heater 222. In some embodiments, the top and the bottom surfaces 252 and 254 may be flat, planar surfaces (or substantially flat, e.g., within 10% or 5% of flat). In some other instances, the top 252, bottom 254, or both top 252 and bottom 254 may be nonplanar surfaces. The nonplanarity of these surfaces may be configured to refract and/or direct the light emitted by the substrate heater 222's LEDs 224 to more efficiently and/or effectively heat the substrate. The nonplanarity may also be along some or all of the surface. For example, the entire bottom surface may have a convex or concave curvature, while in another example an outer annular region of the bottom surface may have a convex or concave curvature while the remaining portion of the surface is planar. In further examples, these surfaces may have multiple, but different, nonplanar sections, such as having a conical section in the center of the surface that is adjacent to a planar annular section, that is adjacent to a conical frustum surface at the same or different angle as the conical section. In some embodiments, the window 250 may have features that act as an array of lenses which are oriented to focus the light emitted by one or more LEDs, such as each LED.

With the window 250 positioned above the substrate heater 222, the window 250 gets heated by the substrate heater 222 which can affect the thermal environment around the substrate. Depending on the material or materials used for the window 250, such as quartz, the window may retain heat and progressively retain more heat over the course of processing one or more substrates. This heat can get radiatively transferred to the substrate and therefore directly heat the substrate. In some instances, that the window can cause a temperature increase of between 50° C. and 80° C. above the heater temperature. This heat may also create a temperature gradient through the thickness, or in the vertical direction, of the window. In some instances, the top surface 252 is 30° C. hotter than the bottom surface 254. It may therefore be advantageous to adjust and configure the chamber to account for and reduce the thermal effects of the window. This may include detecting the substrate's temperature and adjusting the substrate heater to account for the heat retained by the window.

This may also include various configurations of the pedestal, such as actively cooling the window. In some embodiments, like that shown in FIGS. 2A and 2D, the window 250 may be offset from the substrate heater 222 by a first distance 256. In some embodiments, this first distance may be between about 2 mm and 50 mm, including between about 5 mm and 40 mm. A cooling fluid, such as an inert gas, may be flowed between the window 250 and the substrate heater 222 in order to cool both the window 250 and the substrate heater 222. The pedestal may have one or more inlets and one or more outlets for flowing this gas within the plenum volume, or bowl 246, of the pedestal 204. The one or more inlets are fluidically connected to the inert gas source outside the processing chamber 202, which may include through fluid conduits that may be at least partially routed inside the pedestal 204. The one or more outlets are fluidically connected to an exhaust or other environment outside the processing chamber 202, which may also be through fluid conduits running within the pedestal. In FIG. 2E, which depicts the pedestal of FIG. 2D with additional features in accordance with various embodiments, one or more inlets 251 are positioned in the sidewalls 249 and extend through the internal surface 248; the one or more inlets are also fluidically connected to agas source 272 (e.g., an inert gas source) through, in part, fluid conduits 255 that are routed through the pedestal 204. A single outlet 253 is positioned in a center region, i.e., not in the exact center but in close proximity, of the substrate heater 222. In some embodiments, the one or more gas inlets and one or more outlets may be switched, such that the one or more outlets extend through the sidewalls 249 (i.e., they are items 251 in FIG. 2E), and the one or more inlets may be the center region of the substrate heater 222 (i.e., they are item 253 in FIG. 2E). In some embodiments, there may be more than one outlet; in some embodiments, there may only be a single gas inlet. In some embodiments, one or more gas inlets extend through the internal surface 248 of the pedestal sidewall 249 underneath the LED heater 222 and one or more gas outlets extend through another part of the pedestal sidewall 249, such as a mounting bracket between the LED heater 222 and the pedestal sidewall 249.

In some embodiments, the window may be placed in direct, thermal contact with the substrate heater and the pedestal cooler may be configured to cool both the PCB and the window. In some embodiments, as also shown in FIGS. 2A and 2D, the window 250 may be thermally connected to the sidewalls 249 of the pedestal 204 in order to transfer some of the retained heat in the window 250 to the pedestal 204. This transferred heat may be further transferred out of the pedestal using, for instance, the pedestal heater 244 which may flow fluid through the pedestal 204 that is heated to between about 20° C. and 100° C., for instance. This heated fluid may be cooler than the temperature of the pedestal 204 at the thermal connection with the window 250. In some embodiments, the window 250 may have one or more fluid conduits within the window 250 through which transparent cooling fluid may be configured to flow. The fluid may be routed to the window through the pedestal from a fluid source or reservoir outside the chamber.

As shown in FIGS. 2A and 2D, the pedestal's 204 substrate supports 208 are configured to support the substrate 218 above and offset from the window 250 and the substrate heater 222. In certain embodiments, the temperature of the substrate can be rapidly and precisely controlled by thermally floating, or thermally isolating, the substrate within the chamber. It is desirable to position the substrate so that the smallest thermal mass is heated and cooled. This thermal floating is configured to position the substrate so that it has minimal thermal contact (which includes direct and radiation) with other bodies in the chamber.

The pedestal 204 is therefore configured, in some embodiments, to support the substrate 218 by thermally floating, or thermally isolating, the substrate within the chamber interior 214. The pedestal's 204 plurality of substrate supports 208 are configured to support the substrate 218 such that the thermal mass of the substrate 218 is reduced as much as possible to the thermal mass of just the substrate 218. Each substrate support 208 may have a substrate support surface 220 that provides minimal contact with the substrate 218. The number of substrate supports 208 may range from at least 3 to, for example, at least 6 or more. The surface area of the support surfaces 220 may also be the minimum area required to adequately support the substrate during processing operations (e.g., in order to support the weight of the substrate and prevent inelastic deformation of the substrate).

The substrate supports are also configured to prevent the substrate from being in contact with other elements of the pedestal, including the pedestal's surfaces and features underneath the substrate. As seen in FIGS. 2A and 2D, the substrate supports 208 hold the substrate 218 above and offset from the next adjacent surface of the pedestal 204 below the substrate 218, which is the top surface 252 (identified in FIG. 2D) of the window 250. As can be seen in these Figures, a volume or gap exists underneath the substrate, except for the contact with the substrate supports. As illustrated in FIG. 2D, the substrate 218 is offset from the top surface 252 of the window 250 by a distance 258. This distance 258 may affect the thermal effects caused by the window 250 to the substrate 218. The larger the distance 258, the less the effects. It was found that a distance 258 of 2 mm or less resulted in a significant thermal coupling between the window and the substrate; it is therefore desirable to have a larger distance 258 than 2 mm, such as at least about 5 mm, about 10 mm, about 15 mm, about 20 mm, about 30 mm, about 50 mm, or about 100 mm, for example.

The substrate 218 is also offset from the substrate heater 222 (as measured in some instances from a top surface of the substrate heater 222 which may be the top surface of the LEDs 224) by a distance 260. This distance 260 affects numerous aspects of heating the substrate 218. In some embodiments, a distance 260 of between about 10 mm and 90 mm, between about 5 mm and 100 mm, including between about 10 mm and 30 mm, for instance, provides a substantially uniform heating pattern and acceptable heating efficiency.

As stated, the substrate supports 208 are configured to support the substrate 218 above the window. In some embodiments, these substrate supports are stationary and fixed in position; they are not lift pins or a support ring. In some embodiments, at least a part of each substrate support 208 that includes the support surface 220 may be comprised of a material that is transparent at least to light emitted by LEDS 224. This material may be, in some instances, quartz or sapphire. The transparency of these substrate supports 208 may enable the visible light emitted by the LEDs 224 in the substrate heater 222 to pass through the substrate support 208 and to the substrate 218 so that the substrate support 208 does not block this light and the substrate 218 can be heated in the areas where it is supported. This may provide a more uniform heating of the substrate 218 than with a substrate support comprising a material opaque to visible light. In some other embodiments, the substrate supports 208 may be comprised of a non-transparent material, such as zirconium dioxide (ZrO₂).

In some embodiments, the pedestal may be constructed to directly support a substrate (not shown). The pedestal may be configured with lift pins or other movable support members to position a substrate within a deposition zone in an environment of the substrate. A substrate may be moved in a vertical direction within a chamber. In some embodiments, the pedestal includes an electrostatic chuck. The electrostatic chuck may be an uppermost part of the pedestal, and may include one or more electrostatic clamping electrodes embedded within a body of the electrostatic chuck. The substrate may be supported on the top surface of the electrostatic chuck. In some embodiments, the one or more electrostatic clamping electrodes may be coplanar or substantially coplanar. The electrostatic clamping electrodes may be powered by a DC power source or DC chucking voltage (e.g., between about 200 V to about 2000 V) so that the substrate may be retained on the electrostatic chuck by electrostatic attractive forces. Power to the electrostatic clamping electrodes may be provided via first electrical lines that is connected to the electrostatic clamping electrodes. The electrostatic chuck may further include one or more heating elements embedded within the body of the electrostatic chuck. The one or more heating elements may include resistive heaters. In some embodiments, the one or more heating elements are positioned below the one or more electrostatic clamping electrodes. The one or more heating elements may be configured to heat the substrate to a temperature greater than about 200° C., greater than about 450° C., greater than about 500° C., greater than about 550° C., greater than about 600° C., or greater than about 650° C. The one or more heating elements provide selective temperature control to the substrate. Power to the one or more heating elements may be provided via second electrical lines connecting the one or more heating elements and a power source.

In some embodiments, such as those shown in FIG. 2D, the substrate supports 208 may be positioned closer to a center axis 262 of the window than the outer diameter 264 of the window 250. In some instances, portions of these substrate supports may extend over and above the window 250.

In some embodiments, the substrate supports may each contain a temperature sensor that is configured to detect the temperature of the substrate positioned on the support surface of the substrate supports. FIG. 2F depicts a substrate support of FIGS. 2A and 2D in accordance with disclosed embodiments. Here, the support surface 220 of the substrate support 208 is identified, along with a temperature sensor 266. In some embodiments, this temperature sensor 266 extends through the support surface 220 such that the temperature sensor 266 is in direct contact with a substrate held by the support surface 220. In some other embodiments, the temperature sensor 266 is positioned within the substrate support 208 and below the support surface 220. In some embodiments, this temperature sensor 266 is a thermocouple. In some other embodiments, the temperature sensor 266 may be a thermistor, a resistance temperature detector (RTD), and semiconductor sensor. The electrical wiring 268 for the temperature sensor 266 may be routed through the substrate support 208 and may also be routed through the pedestal 204.

Referring back to FIG. 2A, in some embodiments, the pedestal is also configured to move vertically. This may include moving the pedestal such that a gap 286 between a faceplate 276 of the gas distribution unit 210 and the substrate 218 is capable of being in a range between about 2 mm and 70 mm. Moving the pedestal vertically may enable active cooling of the substrate as well as rapid cycling time of processing operations, including flowing gas and purging, due to a low volume created between the gas distribution unit 210 and the substrate 218. This movement may also enable the creation of a small process volume between the substrate and the gas distribution unit which can result in a smaller purge and process volumes and thus reduce purge and gas movement times and increase throughput.

The gas distribution unit 210 is configured to flow process gases, which may include liquids and/or gases, such as a reactant, modifying molecules, converting molecules, or removal molecules, onto the substrate 218 in the chamber interior 214. In some embodiments, the process gases may include phosphine. In some embodiments, the process gas may include hydrogen fluoride (HF), oxygen, ozone, carbon monoxide (CO), carbon dioxide (CO), nitrous oxide (N₂O), nitric oxide (NO), nitrogen dioxide (NO₂), or combination thereof. As seen in FIG. 2A, the gas distribution unit 210 includes one or more fluid inlets 270 that are fluidically connected to one or more gas sources 272 and/or one or more vapor sources 274. The gas distribution unit 110 and other units or parts that may be fluidly in contact with the process gases may be designed and fabricated to be chemically resistant or chemically inert to the process gases. In some embodiments, the gas lines and mixing chamber may be heated to prevent unwanted condensation of the vapors and gases flowing within. These lines may be heated to at least about 40° C., at least about 80° C., at least about 90° C., at least about 100° C., at least about 120° C., at least about 130° C., or at least about 150° C. The one or more vapor sources may include one or more sources of gas and/or liquid which is vaporized. In some embodiments, the one or more sources of gas and/or liquid includes water vapor, alcohol (including but not limited to methyl alcohol, ethyl alcohol, isopropyl alcohol, butyl alcohol), diphosphorus trioxide (P₂O₃), phosphorus trichloride, phosphorus oxychloride, methoxy phosphine, alkyl phosphine halide, trimethyl phosphine, triethyl phosphine, tripropyl phosphine, and/or mixtures thereof. In some embodiments, the one or more sources of gas and/or liquid may be provided by atomizer as a fine spray without heating to an elevated temperature the one or more sources of gas and/or liquid. In some embodiments, the one or more sources of gas and/or liquid may be further diluted by one or more suitable solvents or liquids designed to be suitable for atomization. The vaporizing may be a direct inject vaporizer, a flow over vaporizer, or both. In some embodiments, one or more vapor sources and one or more process gases may be configured to operate either sequentially or concurrently. For example, one vapor source such as water vapor and one process gas such as phosphine may be supplied to the interior of the reaction chamber in a sequential order or concurrently. The gas distribution unit 210 also includes the faceplate 276 that includes a plurality of through-holes 278 that fluidically connect the gas distribution unit 210 with the chamber interior 214. These through-holes 278 are fluidically connected to the one or more fluid inlets 270 and also extend through a front surface 277 of the faceplate 276, with the front surface 277 configured to face the substrate 218. In some embodiments, the gas distribution unit 210 may be considered a top plate and in some other embodiments, it may be considered a showerhead.

The through-holes 278 may be configured in various ways in order to deliver uniform gas flow onto the substrate. In some embodiments, these through-holes may all have the same outer diameter, such as between about 0.03 inches and 0.05 inches, including about 0.04 inches (1.016 mm). These faceplate through-holes may also be arranged throughout the faceplate in order to create uniform flow out of the faceplate.

Referring back to FIG. 2A, the gas distribution unit 210 may also include a unit heater 280 that is thermally connected to the faceplate 276 such that heat can be transferred between the faceplate 276 and the unit heater 280. The unit heater 280 may include fluid conduits in which a heat transfer fluid may be flowed. Similar to above, the heat transfer fluid may be heated to a temperature range of about 20° C. and 120° C., for example. In some instances, the unit heater 280 may be used to heat the gas distribution unit 210 to prevent unwanted condensation of vapors and gases; in some such instances, this temperature may be at least about 90° C. or 120° C.

In some embodiments, the gas distribution unit 210 may include a second unit heater 282 that is configured to heat the faceplate 276. This second unit heater 282 may include one or more resistive heating elements, fluid conduits for flowing a heating fluid, or both. Using two unit heaters 280 and 282 in the gas distribution unit 210 may enable various heat transfers within the gas distribution unit 210. This may include using the first and/or second unit heaters 280 and 282 to heat the faceplate 276 in order to provide a temperature-controlled chamber, as described above, in order to reduce or prevent unwanted condensation on elements of the gas distribution unit 210.

The apparatus 200 may also be configured to cool the substrate. This cooling may include flowing a cooling gas onto the substrate, moving the substrate close to the faceplate to allow heat transfer between the substrate and the faceplate, or both. Actively cooling the substrate enables more precise temperature control and faster transitions between temperatures which reduces processing time and improves throughput. In some embodiments, the first unit heater 280 that flows the heat transfer fluid through fluid conduits may be used to cool the substrate 218 by transferring heat away from the faceplate 276 that is transferred from the substrate 218. A substrate 218 may therefore be cooled by positioning it in close proximity to the faceplate 276, such as by a gap 286 of less than or equal to 5 mm or 2 mm, such that the heat in the substrate 218 is radiatively transferred to the faceplate 276, and transferred away from the faceplate 276 by the heat transfer fluid in the first unit heater 280. The faceplate 276 may therefore be considered a heat sink for the substrate 218 in order to cool the substrate 218.

In some embodiments, the apparatus 200 may further include a cooling fluid source 273, which may contain a cooling fluid (a gas or a liquid), and a cooler (not pictured) configured to cool the cooling fluid to a desired temperature, such as less than or equal to about 90° C., less than or equal to about 70° C., less than or equal to about 50° C., less than or equal to about 20° C., less than or equal to about 10° C., less than or equal to about 0° C. less than or equal to about −50° C., less than or equal to about −100° C., less than or equal to about −150° C., less than or equal to about −190° C., about −200° C., or less than or equal to about −250° C., for instance. The apparatus 200 includes piping to deliver the cooling fluid to the one or more fluid inlets 270, and the gas distribution unit 210 which is configured to flow the cooling fluid onto the substrate. In some embodiments, the fluid may be in liquid state when it is flowed to the processing chamber 202 and may turn to a vapor state when it reaches the chamber interior 214, for example if the chamber interior 214 is at a low pressure state, such as described above, e.g., between about 0.1 Torr and 10 Torr, or between about 0.1 Torr and 100 Torr, or between about 20 Torr and 200 Torr, for instance. The cooling fluid may be an inert element, such as nitrogen, argon, or helium. In some instances, the cooling fluid may include, or may only have, a non-inert element and/or mixtures, such as hydrogen gas. In certain embodiments, the apparatus may be configured to cool a substrate at one or more cooling rates, such as at least about 5° C./second, at least about 10° C./second, at least about 15° C./second, at least about 20° C./second, at least about 30° C./second, or at least about 40° C./second.

In some embodiments, the apparatus 200 may actively cool the substrate by both moving the substrate close to the faceplate and flowing cooling gas onto the substrate. In some instances, the active cooling may be more effective by flowing the cooling gas while the substrate is in close proximity to the faceplate. The effectiveness of the cooling gas may also be dependent on the type of gas used.

In some embodiments, the apparatus 200 may include a mixing plenum for blending and/or conditioning process gases for delivery before reaching the fluid inlets 270. One or more mixing plenum inlet valves may control introduction of process gases to the mixing plenum. In some other embodiments, the gas distribution unit 210 may include one or more mixing plenums within the gas distribution unit 210. The gas distribution unit 210 may also include one or more annular flow paths fluidically connected to the through-holes 278 which may equally distribute the received fluid to the through-holes 278 in order to provide uniform flow onto the substrate.

The apparatus 200 may also include one or more additional non-contact sensors for detecting the temperature of the substrate. Such sensors may include improved pyrometers, for instance. Although conventional pyrometers are not able to detect certain substrates within particular temperature ranges, the pyrometer described herein overcomes these problems. For instance, the pyrometer is configured to detect multiple emission ranges in order to detect multiple types of substrates, e.g., doped, low doped, or not doped, at various temperature ranges. This includes a configuration to detect emission ranges of about 0.95 microns to about 1.1 microns, about 1 micron, about 1 to about 4 microns, and/or about 8 to 15 microns. The pyrometer is also configured to detect the temperature of a substrate at a shorter wavelength in order to differentiate the signal from the thermal noise of the chamber.

The pyrometer may include an emitter configured to emit infrared signals and a detector configured to receive emissions. Referring to FIG. 2A, the apparatus includes the pyrometer 288 having an emitter within the pyrometer 288 and a detector 290. The pyrometer may be configured to emit signals on one side of the substrate, either the top or the bottom, and configured to receive signals on the other side of the substrate. For instance, the emitter may emit signals on the top of the substrate and the detector is under the substrate and receives signals emitted through and under the substrate. The apparatus may therefore have at least a first port 292A on the top of the processing chamber 202, such as the port 292A through the center of the gas distribution unit 210, and a second port 292B through the pedestal 204 and substrate heater 222. The emitter in the pyrometer 288 may be connected to one of the ports 292A or 292B via a fiberoptic connection, such as the first port 292A as shown in FIG. 2A, and the detector is optically connected to the other port, such as the second port 292B in FIG. 2A. The first port 292A may include a port window 294 to seal the first port 292A from the chemistries within the chamber interior 214. The second port 292B is seen in FIG. 2A extending through the pedestal 204 and the substrate heater such that the emitter's emissions can pass through the substrate, through the window 250, into the second port 292B and to the detector 290 that may be positioned in the second port or optically connected to the second port through another fiberoptic connection (not shown). In some other embodiments, the emitter and the detector are flipped, such that the emitter emits through the second port 292B and the detector detects through the first port 292A.

The apparatus 200 may also include one or more optical sensors 298 to detect one or more metrics of the visible light emitted by the LEDs. In some embodiments, these optical sensors may be one or more photodetectors configured to detect the light and/or light intensity of the light emitted by the LEDs of the substrate heater. In FIG. 2A, a single optical sensor 298 is shown as connected to the chamber interior 214 via fiberoptic connection such that the optical sensor 298 is able to detect light emitted by the substrate heater 222. The optical sensor 298, and additional optical sensors, can be positioned in various locations in the top and sides, for instance, of the processing chamber 202 in order to detect the emitted light at various locations within the processing chamber 202. As discussed below, this may enable the measurement and adjustment of the substrate heater, such as the adjustment of one or more independently controllable zones of the LEDs. In some embodiments, there may be a plurality of optical sensors 298 arranged along a circle or multiple concentric circles in order to measure various regions of the LEDs throughout the processing chamber 202. In some embodiments, the optical sensors may be positioned inside the chamber interior 214.

In some embodiments, the apparatuses described herein may include a controller that is configured to control various aspects of the apparatus in order to perform the techniques described herein. For example, referring back to FIG. 2A, apparatus 200 includes a controller 231 (which may include one or more physical or logical controllers) that is communicatively connected with and that controls some or all of the operations of a processing chamber. The system controller 231 may include one or more memory devices 233 and one or more processors 235. In some embodiments, the apparatus includes a switching system that is operably coupled to the system controller 231 for controlling flow rates and durations, the substrate heating unit, the substrate cooling unit, the loading and unloading of a substrate in the chamber, the thermal floating of the substrate, and the process gas unit, for instance, when disclosed embodiments are performed. For example, the switching system may control flow rates and durations of water vapor in the chamber such that one or more monolayers of water is controllably adsorbed on a substrate, or on the silicon nitride surface. In some embodiments, the apparatus may have a switching time of up to about 500 milliseconds (ms), or up to about 750 ms. Switching time may depend on the flow chemistry, recipe chosen, reactor architecture, and other factors.

In some embodiments, the switching system of the apparatus may be coupled to one or more contact or non-contact sensors to monitor the substrate temperature, one or more temperature sensors operably coupled to the chamber heaters to monitor the chamber temperature, or the gas distribution unit to monitor and control a flow rate and a duration of the one or more gaseous reactant and vapor.

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a PVD chamber or module, a CVD chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers. In some embodiments, example systems may include a combination of an ALD chamber or module and an ALE chamber or module such that one or more depositions are performed on a substrate followed by one or more etching without breaking a vacuum in the chamber or exposing the substrate to an ambient atmosphere.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

In some embodiments, the apparatus may further be configured to generate a plasma and use the plasma for some processing in various embodiments. This may include having a plasma source configured to generate a plasma within the chamber interior, such as a capacitively coupled plasma (CCP), an inductively coupled plasma (ICP), an upper remote plasma, and a lower remote plasma.

The apparatuses described herein may be used for various etching techniques including, but not limited to, continuous etching methods and cyclic methods such as atomic layer etching.

### APPLICATIONS

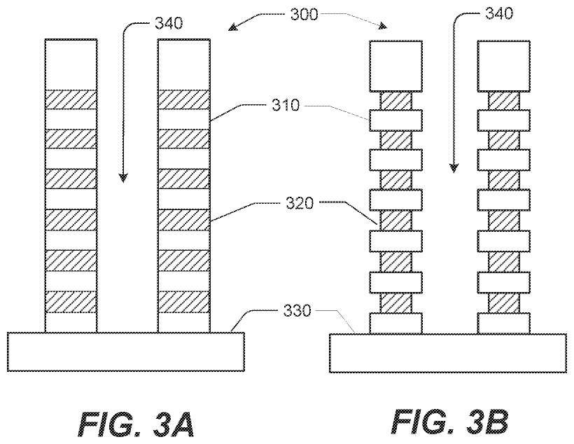

There are various applications where the etch process according to embodiments herein may be used. One application is selectively etching nitride layers in a 3D memory stack. In the fabrication of the 3D NAND or other devices, silicon oxide and silicon nitride layer layers may be alternately deposited to form an oxide/nitride stack. Silicon oxide and silicon nitride layers may be deposited by any suitable process, for example, ALD, PEALD, CVD, or PECVD. The silicon oxide/silicon nitride layer stack may be etched to form a high aspect ratio (HAR) structure with a trench formed between adjacent HAR structures. FIG. 3A is a schematic diagram showing a cross-sectional depiction of a feature prior to atomic layer etch according to some embodiments. The feature on a substrate may be a HAR structure 300 including silicon oxide layers 310 and silicon nitride layer layers 320 alternately stacked on a substrate (i.e., silicon substrate) 330 with a trench 340 formed between neighboring HAR structures 300. Tn some embodiments, the HAR structure may high from about 7 μm and about 10 μm. Each silicon nitride layer thickness may between about 5 nm and 40 nm.

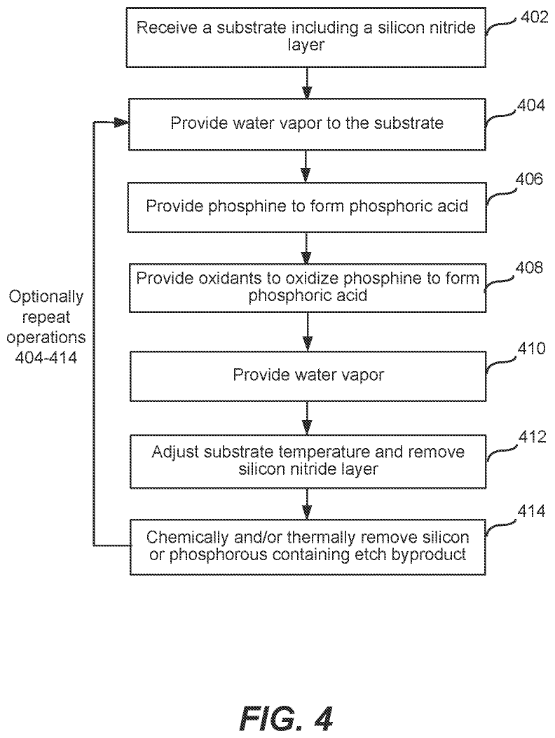

FIG. 3B is a schematic diagram shown a cross-sectional depiction of the HAR structure on the substrate shown in FIG. 3A after atomic layer etch according to some embodiments, where silicon nitride layer 320 are selectively etched to form a recess without attacking neighboring silicon oxide or silicon substrate. A recess depth measured from the surface of the unetched silicon nitride layer in FIG. 3A in a horizontal direction may range from about 1 to about 20 nm. The process for etching silicon nitride layer 320 may be described in a process flow shown in FIG. 4. A semiconductor substrate including one or more HAR structures including one or more silicon nitride layers is supplied in a reaction chamber (operation 402). The reaction chamber temperature may be about 20° C., and chamber pressure may be about 10 Torr. At operation 404, water vapor is supplied to the chamber interior such that one or more monolayers of water molecules are adsorbed on the surface of the HAR structure 300 including silicon nitride layers 320. At operation 406, gaseous phosphine is supplied to the adsorbed water layer to form phosphoric acid on the structure surfaces. At operation 408, oxidants such as oxygen, ozone, carbon monoxide (CO), carbon dioxide (CO₂), nitrous oxide (N₂O), nitric oxide (NO), nitrogen dioxide (NO₂), and/or mixtures thereof are subsequently supplied to the surfaces of the HAR structure 300 to oxidize unreacted phosphine to P₂O₅, which may react with water provided at operation 404 or water in the reaction chamber to in situ generate phosphoric acid. In some embodiments, the amount of silicon nitride removed by phosphoric acid may depend on the reaction chamber temperature (or substrate temperature), and may not be significant at operations 406-408. It is noted that operations 406 and 408 may be configured to occur simultaneously or substantially simultaneously.

Subsequently, water vapor is provided to the surface of the structure 300 (operation 410), and the substrate temperature may be adjusted to above 100° C., or to between about 100° C. and about 180° C., or between about 120° C. and about 180° C. (operation 412). Providing additional water under high temperature increases the amount of phosphoric acid generated, and also increase the reaction of phosphoric acid with the silicon nitride layer. Operation 412 involves a substantial etching of silicon nitride layer 320. Phosphoric acid selectively etches silicon nitride layer 320 over neighboring silicon oxide 310 and/or silicon substrate 330. Silicon nitride layer 320 is etched from the surface, forming a recess as shown in FIG. 3B. Silicon nitride layer etch may progress substantially in a horizontal direction. The degree of etching in silicon nitride layer may be determined by, for example, the amount of water vapor, substrate temperature, and/or etch time. Removal of silicon nitride by phosphoric acid generates one or more etch byproducts. The etch byproducts may include silicon, e.g., orthosilicic acid (Si(OH)₄), or phosphorus, e.g., phosphorus oxide (P₂O₅). The etch byproducts may remain on the surface of the silicon nitride layers in the HAR structure. At operation 414, the etch byproducts may be removed from the silicon nitride layer surfaces by heating the substrate above about 100° C., or above about 120° C., or between about 100° C. and about 120° C., or above about 130° C., or above about 140′C while reacting with a suitable etch compound such as hydrogen fluoride that may dissociate the etch byproduct into a volatile byproduct. Alternately, the etch product such as P₂O₅ may be removed by thermal sublimation above about 360° C., or above about 375° C., or above about 400° C. P₂O₅ may be removed by reacting with hydrogen fluoride to generate PF₅. Depending on the recess depth required in the silicon nitride layer, the operations 404-414 (or operations 406-414) may be optionally repeated until the desired portion of the silicon nitride layer is etched.

The atomic layer etch process according to some embodiments excludes supplying reactants in liquid form. Instead, only gaseous reactants are supplied into the chamber to in situ generate gaseous etch chemistry, allowing an uniform etch reaction throughout the location on the surfaces of silicon nitride layer. For a high density memory device with increased number of cells having a smaller cell size, capillary force of liquid etch chemistry from the wet etch may affect the stability of the features or the stack. The nitride etch process according to some embodiments may not be affected by capillary force due to nature of gaseous reactants involved. The etch process also allows to control the etch down to the level of angstrom scale by controlling parameters including flow rate and duration of water vapor, substrate temperature, or duration time.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1-10. (canceled)

11. A method of treating a silicon nitride layer, the method comprising:
(a) generating a phosphoric acid on a surface of the silicon nitride layer; and
(b) treating the surface of the silicon nitride layer using the phosphoric acid.

12. The method of claim 11 further comprising (c), prior to (a), providing water vapor to form one or more monolayers of water molecules on the surface of the silicon nitride layer.

13. The method of claim 11, wherein the temperature at the surface of the silicon nitride layer ranges between about 0° C. and about 100° C., and the pressure at the surface of the silicon nitride layer ranges between about 1 Torr and about 100 Torr.

14. The method of claim 11, wherein generating the phosphoric acid comprises:
providing a first reactant;
providing a second reactant; and
reacting the first reactant and the second reactant to form the phosphoric acid,
wherein the first reactant comprises phosphorus.

15. The method of claim 14, wherein the first reactant is selected from the group consisting of phosphine, diphosphorus trioxide (P₂O₃), phosphorus trichloride, phosphorus oxychloride, methoxy phosphine, alkyl phosphine halide, trimethyl phosphine, triethyl phosphine, tripropyl phosphine, and/or mixtures thereof.

16. The method of claim 14, wherein the second reactant is selected from the group consisting of oxygen, ozone, carbon monoxide (CO), carbon dioxide (CO₂), nitrous oxide (N₂O), nitric oxide (N₂O), nitrogen dioxide (NO₂), and/or mixtures thereof.

17. The method of claim 11, further comprising:
providing water vapor; and
prior to or during providing the water vapor, adjusting the temperature to no less than about 100° C.

18. The method of claim 11, wherein treating the surface of the silicon nitride layer comprises:
etching a portion of the surface of the silicon nitride layer, and
generating an etch byproduct.

19. The method of claim 11, further comprising:
removing an etch byproduct from the surface of the silicon nitride layer by:
(i) heating to no less than about 360° C.,
(ii) heating to between about 100° C. and about 120° C. while reacting with hydrogen fluoride, or
(iii) reacting with hydrogen fluoride,
wherein the etch byproduct comprises phosphorus or silicon.

20. The method of claim 11, wherein generating the phosphoric acid comprises:
co-flowing a first reactant comprising phosphorus, and a second reactant,
wherein the first reactant is selected from the group consisting of phosphine, diphosphorus trioxide (P₂O₃), phosphorus trichloride, phosphorus oxychloride, methoxy phosphine, alkyl phosphine halide, trimethyl phosphine, triethyl phosphine, tripropyl phosphine, and/or mixtures thereof, and
wherein the second reactant is selected from the group consisting of oxygen, ozone, carbon monoxide (CO), carbon dioxide (CO₂), nitrous oxide (N₂O), nitric oxide (N₂O), nitrogen dioxide (NO₂), and/or mixtures thereof.

21. A method of etching a silicon nitride layer in a reaction chamber, the method comprising:
providing a semiconductor substrate comprising the silicon nitride layer in the reaction chamber;
providing a first water vapor to form one or more monolayers of water molecules on the surface of the silicon nitride layer;
providing phosphine to the surface of the silicon nitride layer; and
providing an oxidant to the phosphine to in situ generate a phosphoric acid on the silicon nitride layer.

22. The method of claim 21, wherein the temperature at the surface of the silicon nitride layer ranges between about 0° C. and about 100° C., and the pressure at the surface of the silicon nitride layer ranges between about 1 Torr and about 100 Torr.

23. The method of claim 21, wherein the oxidant is selected from the group consisting of oxygen, ozone, carbon monoxide (CO), carbon dioxide (CO₂), nitrous oxide (N₂O), nitric oxide (N₂O), nitrogen dioxide (NO₂), and/or mixtures thereof.

24. The method of claim 21, further comprising:
providing a second water vapor in the reaction chamber; and
prior to or during providing the water vapor, adjusting the temperature to no less than about 100° C.

25. The method of claim 21, further comprising:
generating an etch byproduct comprising silicon or phosphorus; and
removing the etch byproduct from the surface of the silicon nitride layer by:
(i) heating the etch byproduct to no less than about 360° C., or
(ii) heating to between about 100° C. and about 120° C. while reacting with hydrogen fluoride, or
(iii) reacting with hydrogen fluoride.

26. An apparatus to process a substrate, the apparatus comprising:
a process chamber for processing the substrate;
a pedestal comprising one or more heating elements to heat the substrate;
a gas distribution unit for delivering one or more gaseous reactants to the substrate;
a controller configured to:
control the gas distribution unit to control flow rates and durations of the one or more gaseous reactants and/or vapors, and
control the operation of the heating element to control the temperature of the substrate.

27. The apparatus of claim 26, wherein the one or more heating elements are positioned on the backside of the substrate.

28. The apparatus of claim 26, wherein the pedestal is spaced from the substrate by a predetermined distance.

29. The apparatus of claim 26, wherein the pedestal is in direct contact with the substrate.

30. The apparatus of claim 26, wherein the one or more gaseous reactants comprises: water vapor; a first reactant selected from the group consisting of phosphine, diphosphorus trioxide (P₂O₃), phosphorus trichloride, phosphorus oxychloride, methoxy phosphine, alkyl phosphine halide, trimethyl phosphine, triethyl phosphine, tripropyl phosphine, and/or mixtures thereof; a second reactant selected from the group consisting of oxygen, ozone, carbon monoxide (CO), carbon dioxide (CO₂), nitrous oxide (N₂O), nitric oxide (NO), nitrogen dioxide (NO₂), and/or mixtures thereof; or hydrogen fluoride.
